(19) United States
(12) Patent Application Publication
(10) Pub. No.: US 2025/0224435 A1
(43) Pub. Date: Jul. 10, 2025

(54) ANTENNA DEVICE FOR OTA DEVICE TESTING USING AUTOMATED TEST EQUIPMENT

(71) Applicant: Advantest Corporation, Tokyo (JP)

(72) Inventors: José Moreira, San Jose, CA (US); Sergey Churkin, San Jose, CA (US); Maxim Muravyev, San Jose, CA (US); Nikita Bulygin, San Jose, CA (US); Andrey Mozharovskiy, San Jose, CA (US); Alexey Artemenko, San Jose, CA (US)

(21) Appl. No.: 19/092,008

(22) Filed: Mar. 27, 2025

Related U.S. Application Data
(63) Continuation of application No. PCT/EP2022/076877, filed on Sep. 27, 2022.

(51) Int. Cl. G01R 29/08; G01R 31/28

(52) U.S. Cl. CPC G01R 29/0871; G01R 31/2834

(57) ABSTRACT

Embodiments of the present invention provide a novel antenna device for OTA testing and measurement using an antenna disposed in a socket of automatic test equipment (ATE) that provides high bandwidth for devices testing and measurement. The antenna device can include a printed circuit board (PCB) including an opening with at least two probes disposed on or in the printed circuit board orthogonally to each other and a cavity between a portion of the PCB carrying the probes and a waveguide backshort. The cavity forms a dual-polarized waveguide between the portion of the PCB carrying the probes and the waveguide backshort, which is typically a reflective termination placed at the end of the waveguide. According to some embodiments, the cavity has a depth of a quarter wavelength, λ/4, plus an integer multiple of a half wavelength, within a tolerance of +/− 1/16 of the wavelength.

### CROSS-REFERENCE TO RELATED APPLICATION

This application is a continuation of copending International Application No. PCT/EP2022/076877, filed Sep. 27, 2022, which is incorporated herein by reference in its entirety.

### FIELD

Embodiments of the present invention generally relate to the field of device testing. More specifically, embodiments of the present invention relate to over the air (OTA) device testing and are related to automated test equipment.

### BACKGROUND

Over-the-Air (OTA) device testing is a method used to evaluate the wireless performance and reliability of devices with embedded antennas, such as smartphones, smartwatches, IoT devices, and other wireless gadgets. Unlike traditional device testing, which involves wired connections to a device's antenna ports, OTA testing simulates real-world conditions by assessing the device's performance through one or more antennas. This approach is critical for ensuring that devices can handle actual usage scenarios, including wireless signal strength, radiation patterns, and interference from surrounding objects or body parts.

OTA testing typically takes place in a controlled environment, such as an anechoic chamber, which is designed to absorb electromagnetic reflections and mimic free-space conditions. The device under test (DUT) is placed in the chamber and surrounded by antennas that emit controlled electromagnetic waves. Unfortunately, using antennas in a socket for OTA testing and measurements produces several challenges. For example, OTA testing and measurement of an antenna in package (AiP) antenna array requires different a antenna design for, and therefore relying on the antenna topology used for an AiP antenna array (e.g., a 5G module) is insufficient.

Moreover, the measuring antenna is often a single antenna (not an array). Therefore, the size of the antenna is not critical. Furthermore, the antenna gain is not critical since it is used in the radiating near-field and the entire measurement setup is calibrated. It is also desirable (or even critical in some cases) to provide a large enough bandwidth to cover all frequencies to be tested.

### SUMMARY

Accordingly, there is a need in the art for an approach to device testing and measurement using an antenna that can be disposed within a socket and that provides a relatively large bandwidth for OTA testing using automated test equipment (ATE). Embodiments of the present invention provide a novel antenna device for OTA testing and measurement using an antenna disposed in a socket of automatic test equipment (ATE) that provides high bandwidth for devices testing and measurement. The antenna device can include a printed circuit board (PCB) including an opening with at least two probes disposed on or in the printed circuit board orthogonally to each other and a cavity between a portion of the PCB carrying the probes and a waveguide backshort. The cavity forms a dual-polarized waveguide between the portion of the PCB carrying the probes and the waveguide backshort, which is typically a reflective termination placed at the end of the waveguide. According to some embodiments, the opening in the printed circuit board is disposed in a central area around a central axis of the cavity, and the cavity has a depth of a quarter wavelength, λ4, plus an integer multiple of a half wavelength, within a tolerance of +/− 1/16 of the wavelength.

According to one embodiment, an antenna device is disclosed, including a cavity, a waveguide backshort, and a PCB, where the PCB includes an opening and is operable to accommodate at least two probes on a portion of the PCB disposed orthogonally to each other, where the cavity is arranged between the portion of the PCB accommodating the probes and the waveguide backshort, where the cavity is configured to form a dual-polarized waveguide between the portion of the PCB accommodating the probes and the waveguide backshort, where the opening in the PCB is arranged in a central area around a central axis of the cavity, and where further the cavity includes a depth of a quarter wavelength plus an integer multiple of half the wavelength, within a tolerance of +/− 1/16 of the wavelength.

According to some embodiments, the at least two probes are accommodated on the PCB in an area of the PCB surrounding the cavity located between the PCB and the waveguide backshort.

According to some embodiments, the probes include at least one orthogonal pair of probes, and the probes are operable to excite at least two orthogonal modes of the waveguide.

According to some embodiments, the antenna device includes at least two microstrip lines disposed on the PCB in an area of the PCB which does not surround the cavity between the PCB and the waveguide backshort, the at least two probes are connected to the at least two microstrip lines, and the at least two microstrip lines form respective feeding networks for the at least two probes.

According to some embodiments, the antenna device includes at least two differential ports, and at least two differential line transitions, where the respective feeding networks of the at least two probes are coupled to respective differential ports out of the at least two differential ports via respective differential line transitions of the at least two differential line transitions.

According to some embodiments, the antenna device includes a first feeding network of the respective feeding networks of the probes has a first orientation, a second feeding network of the respective feeding networks of the probes has a second orientation orthogonal to the first orientation, and the first and second feeding networks are disposed on different layers of the PCB.

According to some embodiments, the antenna device includes four probes that are operable to be accommodated by the PCB in an area of the PCB that surrounds the cavity disposed between the PCB and the waveguide backshort, where the four probes are disposed on the PCB in two orthogonal pairs, and where further the four probes are operable to excite main orthogonal modes, TE₁₀ and TE₀₁, of the waveguide.

According to some embodiments, the antenna device includes a first differential port, a second differential port, and four microstrip lines, where the four microstrip lines are disposed on the PCB in an area of the PCB that does not surround the cavity disposed between the PCB and the waveguide backshort, and the four probes are coupled with respective microstrip lines of the four microstrip lines.

According to some embodiments, the antenna device includes including a metal base plate, where the PCB is disposed on a surface of the metal base plate, and where the cavity passes through the metal base plate.

According to some embodiments, the PCB includes a multi-layer PCB, where the waveguide backshort is implemented using a layer of the PCB, and where the multi-layer PCB includes vias around the cavity.

According to some embodiments, the cavity includes a width of half a wavelength, and where the at least two probes include a length that is equal to the depth of the cavity within a tolerance of 1/16 of the wavelength.

According to some embodiments, the at least two probes are operable to pass through multiple layers of the PCB through a probe via.

According to some embodiments, the antenna device includes an upper metal plate, where an additional waveguide portion is formed in the upper metal plate, and the additional waveguide portion extends the waveguide formed by the cavity.

According to some embodiments, the antenna device includes a metal base plate, the PCB is disposed between the metal base plate and the upper metal plate, and the cavity passes through the metal base plate.

According to some embodiments, the antenna device includes a plurality of external connections, where a first external connection of the plurality of external connections is operable to be coupled with one or more of the at least two probes having a first orientation, and where a second external connection of the plurality of external connections is operable to be coupled with one or more of the at least two probes having a second orientation.

According to some embodiments the plurality of external connections include blind mating waveguide connections, and where the plurality of external connections are aligned towards a main radiation direction.

According to some embodiments, the antenna device includes a radio transparent cover that substantially covers the waveguide, and is operable to push a device under test into a device under test location while allowing for a transit of electromagnetic radiation between the waveguide to the device under test.

According to a different embodiment, an automated test equipment (ATE) is disclosed, including an antenna device including a cavity, a waveguide backshort, and a printed circuit board (PCB), where the PCB includes an opening. The PCB is operable to accommodate at least two probes on a portion of the PCB orthogonally to each other, and the cavity is arranged between the portion of the PCB accommodating the probes and the waveguide backshort. The cavity is configured to form a dual-polarized waveguide between the portion of the PCB accommodating the probes and the waveguide backshort, where the opening in the printed circuit board is arranged in a central area around a central axis of the cavity. The cavity includes a depth of a quarter wavelength plus an integer multiple of half the wavelength, within a tolerance of +/− 1/16 of the wavelength. The ATE further includes measurement instrumentation operable to test a device under test using the antenna device.

According to some embodiments, the antenna device further includes a device under test (DUT) socket, and one or more high frequency connectors arranged proximate to the DUT socket.

According to some embodiments, the antenna device further includes one or more external connections, and a cover. The one or more external connections are operable to couple with the one or more high frequency connectors, and the cover is operable to push the device under test into the device under test socket when the one or more external connections of the antenna device couple with the one or more high frequency connectors.

Embodiments according to the invention can be used for far-field and radiating near field over the air testing, as well as for applications like 5G, 6G, WiGig and mm Wave Radar.

According to an aspect, embodiments according to the invention can be applied to provide an optimized concept of OTA testing using automated test equipment.

According to an embodiment, an antenna device may have: a printed circuit board (PCB), including an opening, wherein at least two probes are arranged on or in the printed circuit board orthogonally to each other; a cavity between a portion of the PCB carrying the probes and a waveguide backshort, the cavity forming a dual-polarized waveguide between the portion of the PCB carrying the probes and the waveguide backshort; wherein the opening in the printed circuit board is arranged in a central area around a central axis of the cavity; wherein the cavity has a depth of a quarter wavelength, λ/4, plus an integer multiple of a half wavelength, within a tolerance of +/− 1/16 of the wavelength.

Another embodiment may have an automated test equipment (ATE), wherein the automated test equipment includes an antenna device according to one of the preceding claims, wherein the automated test equipment is configured to test a device under test using the antenna device.

Another embodiment may have an automated test equipment, wherein the automated test equipment includes a device under test socket and one or more high frequency connectors, wherein the one or more high frequency connectors are arranged beside the test socket.

An embodiment according to the invention creates an antenna device, e.g. OTA socket measurement antenna device, e.g. wideband antenna device, comprising: a printed circuit board (PCB), comprising an opening, e.g. an approximately squared hole, wherein at least two, e.g. orthogonal, e.g. pin, probes are arranged on or in the printed circuit board orthogonally to each other, e.g. to couple with two orthogonal modes of the waveguide; a cavity, e.g. a backshort cavity, e.g. a cavity having a rectangular cross-section or having a squared cross section or having a circular cross section, between a portion of the PCB carrying the probes, e.g. an aperture cutout or a plurality of layers of the PCB carrying the probes; and a waveguide backshort, which may, for example, be formed by a metal base plate or which may, for example, be formed by a layer of a multi-layered PCB. The cavity forms a waveguide (a dual-polarized waveguide), e.g. a rectangular hollow waveguide or a squared hollow waveguide, or a circular hollow waveguide, between the portion of the PCB carrying the probes and the waveguide backshort. The opening in the printed circuit board is arranged in a central area around a central axis of the cavity. The cavity has a depth of a quarter wavelength, e.g. a guided wavelength in the waveguide formed by the cavity, λ/4, plus an integer multiple of a half wavelength, wherein the integer may be equal to zero or larger to zero; wherein the wavelength is set at device's center frequency.

It should be noted that technically reasonable tolerances should be considered. For example, acceptable tolerances of the dimensions (e.g. with respect to the depth of the cavity) may be +/− 1/16 of a wavelength, or may be +/−⅛ of a wavelength.

It should be noted that embodiments create a very wideband device, hence, the wavelength naturally varies when shifting from center frequency to band's edges. In some cases, the variation can exceed the specified 1/16 tolerance on physical length of the backshort.

This embodiment according to the invention is based on the finding that providing the distance between the probes and the backshort plate of a quarter wavelength provides wideband antenna operational frequency range in the antenna device. Moreover, the embodiment is based on the finding that an antenna structure with good properties can be implemented if the antenna comprises the above mentioned waveguide transition with a backshort. It has been found that, for a good or proper operation, it is advantageous that the waveguide backshort has a quarter wavelength.

Therefore, no change of antenna is needed to cover the different frequency bands, which minimizes the costs of the implementation.

Moreover, it has been found that the described antenna geometry is well-suited for coupling with one or more antennas of a device under test (DUT) in an automated test equipment. For example, the cavity between the printed circuit board and the backshort may provide a good matching, may also help to efficiently couple to the radiating nearfield of a DUT antenna. Also, it has been found that the cavity improves wideband characteristics of the antenna structure.

According to an embodiment, the probes are disposed in or on the printed circuit board, in an area of the printed circuit board which bounds the cavity between the printed circuit board and the waveguide backshort, e.g. such that the probes couple with electromagnetic modes of cavity. Such disposition of the probes, e.g. inside an aperture cutout, is configured so as the probes excite main orthogonal modes of the waveguide. However, the geometry may also allow a coupling to other modes of the waveguide, like evanescent modes that couple to the radiating nearfield of the DUT antenna.

According to an embodiment, the probes form at least one orthogonal pair of probes, which is configured to excite at least two orthogonal modes of the waveguide, e.g. (TE₁₀ & TE₀₁). This allows for a testing of devices which receive or transmit using different polarizations or using circular polarization.

According to an embodiment, the probes are connected to at least two microstrip lines formed on or in the printed circuit board in an area of the printed circuit board which does not bound the cavity between the printed circuit board and the waveguide backshort, wherein the microstrip lines form feeding networks of the probes, which are, for example, connected to ports via transmission lines. Such a concept allows for a cost-efficient implementation, since, for example, both the probes and the feeding can be realized on a single printed circuit board. An appropriate impedance of the feed lines or even an impedance matching functionality can be implemented by an appropriate geometrical layout (or design) (or impedance) of the feed lines.

According to an embodiment, the feeding networks of the probes are connected to respective differential ports via respective differential line transitions. Differential feeding helps to provide symmetry to antenna circuit, increases decoupling between orthogonal arms and widens operational bandwidth. The feeding networks could, for example, be connected to differential line transitions, e.g. with 100 Ohm differential interfaces. This provides versatility of antenna circuit integration to transceiver chain components on the same board.

According to an embodiment, the feeding networks of one or more of the probes having a first orientation and the feeding networks of one or more of the probes having a second orientation, which is orthogonal to the first orientation, e.g. a first probe of an orthogonal pair and a second probe of an orthogonal pair, are disposed on different, e.g. opposite, layers of the printed circuit board, e.g. with a ground layer in between, such that the ground layer shields the different feeding networks even in a region where the different feeding networks comprise a crossing when seen in a projection onto the PCB plane. Disposition of the feeding networks of the probes on the opposite layers of the PCB provides ease of routing and high isolation. This enables PCB process simplicity because no blind/buried via is needed. Moreover, fabrication of multi-layered printed circuit boards is nowadays a standard technology and allows for a cost-efficient solution with good characteristics. Moreover, the usage of a multi-layered PCB at the same time allows for a quasi-three-dimensional shaping of the probes, using multiple layers.

According to an embodiment, the antenna device comprises four probes, which are arranged in two orthogonal pairs, which are disposed in or on the printed circuit board, in an area of the printed circuit board which bounds the cavity between the printed circuit board and the waveguide backshort, e.g. such that the probes couple with modes of cavity, and which are configured to excite main orthogonal modes, TE₁₀ and TE₀₁, of the waveguide. However, the probes may (optionally) also couple to other modes of the waveguide, which may be advantageous under nearfield conditions.

According to an embodiment, the four probes are connected with respective microstrip lines in or on the printed circuit board in an area of the printed circuit board which does not bound the cavity between the printed circuit board and the waveguide backshort, wherein two probes having a first orientation, e.g. two collinear probes, are coupled to a first differential port, e.g. using respective microstrip lines and/or using two differential transmission lines, and wherein two probes having a second orientation, two further collinear probes, are coupled to a second differential port, e.g. using respective microstrip lines and/or using two further differential transmission lines. Differential feeding helps to provide symmetry to antenna circuit, increases decoupling between orthogonal arms and widens operational bandwidth.

According to an embodiment, the printed circuit board comprises at least three layers, advantageously four layers. So called “thick probes” (e.g. using multiple layers of the printed circuit board, which may be connected using vias) may thus be created. Consequently, for example, a good (e.g. broadband) coupling between the probes and the fields within the waveguide can be achieved with small effort. For example, it has been found that thickening the probes along the dimension perpendicular to PCB widens operational bandwidth. Also using multiple PCB layers helps to improve matching and broadband characteristics.

According to an embodiment, the printed circuit board is arranged, e.g. attached, on a surface of, e.g. on top of, a metal base plate, and the cavity is formed in the metal base plate, e.g. in an upper part of the metal base plate, wherein e.g. the metal base plate also forms the waveguide backshort. A decreased size of the antenna device is thus provided. Also, fabrication is relatively simple, wherein milling technology may, for example, be used.

According to an embodiment, the printed circuit board is a, e.g. thick, multi-layer printed circuit board, e.g. comprising more than 4 layers; e.g. comprising 8 or more layers; and the waveguide backshort is implemented using a layer, e.g. a metal layer, of the printed circuit board, as a PCB layer; and/or boundaries, e.g. sidewall boundaries, of the cavity are implemented using vias through the multi-layer printed circuit board, e.g. using plated through via holes which may, for example, extend through a plurality of layers of the PCB. A through hole inside the aperture cutout could be provided for increasing antenna bandwidth. Such an approach allows for a cost-efficient fabrication of the antenna structure using PCB fabrication technology. Even though the characteristic of the cavity (e.g. of the cavity walls) are not optimal using such an approach, it has been found that the characteristics of such a structure are still sufficiently good for many testing requirements.

According to an embodiment, the cavity has a width of a half wavelength, λ/2. It has been found that such dimensions result in good characteristics of the antenna structure.

According to an embodiment, the probes have a length that is equal to the depth of the cavity within a tolerance of 1/16 of the wavelength. It has been recognized that such dimensions provide particularly good antenna characteristics.

According to an embodiment, the probes pass through several layers of the PCB connected through one or more probe vias. It has been recognized that this increases broadband performance of the antenna structure while being implementable at reasonable cost.

According to an embodiment, the antenna device further comprises an upper metal plate, wherein an additional waveguide portion is formed in the upper metal plate, such that the additional waveguide portion is an extension of the waveguide formed by the cavity. The additional waveguide portion increases an antenna bandwidth.

According to an embodiment, the printed circuit board is arranged between the metal base plate and the upper metal plate. Two-portions waveguide is thus provided. Moreover, a feed structure can be easily fabricated using such a layout (or design), e.g. by milling tranches in the metal base plate or in the upper metal plate, e.g. along feed traces on the printed circuit board.

According to an embodiment, the differential transmission lines comprise shielding thereon. An improved isolation is provided. Such shielding can, for example, be provided using the metal base plate and/or the upper metal plate.

According to an embodiment, the antenna device comprises one or more external connections, e.g. blind mating waveguide connections, wherein a first external connection, e.g. a first waveguide connection, is coupled with one or more of the probes having a first orientation, and/or wherein a second external connection, e.g. a second waveguide connection, is coupled with one or more probes having a second orientation, which may be orthogonal to the first orientation. An improved routing and isolation is provided then. Using such connections, the antenna device can, for example, be coupled with one or more signal sources and/or one or more signal receivers of an automated test equipment. Thus, the antenna device may, for example, be coupled to a test head of an automated test equipment using the one or more external connectors.

According to an embodiment, the one or more external connections are waveguide connections. It has been recognized that waveguide connections comprise a particularly small wear-out and are therefore well-suited for volume test in which the antenna device is connected with and disconnected from an automated test equipment very often.

According to an embodiment, the one or more external connections are blind mating connections, e.g. blind-mating waveguide connections. The blind-mating waveguide connections could be used, for example, for connecting the measurement antenna millimeter wave signals to the measurement instrumentation of the automated test equipment. The blind mating capabilities of the external connectors allow for a rapid connection and disconnection, e.g. controlled by a robot handler. Thus, a high test throughput is enabled.

According to an embodiment, the one or more external connections are aligned towards a direction, e.g. to make contact in a direction, which is identical to a main radiation direction of the antenna device. Accordingly, the antenna device can be placed “on top” of a device under test, which may, for example, be placed in a test socket arranged on a DUT board, and route back the signals in a direction towards the DUT board (e.g. in a direction towards an opening in the DUT port, in which a high frequency connection is located).

According to an embodiment, the antenna device comprises an electromagnetically permeable, e.g. electromagnetically transparent, cover, which covers the waveguide. Thus, the waveguide can be protected, and the cover may also serve to push the device under test into its desired position (e.g. into a test socket).

According to an embodiment, the cover is configured to push a device under test into a device under test location, e.g. into a test socket, while allowing for a transit of electromagnetic radiation from the waveguide to the device under test or vice versa. Thus, the antenna device can (at least partially) take over the functionality of a pusher, which helps to reduce costs and accelerate an exchange of the device under test.

An embodiment according to the invention creates an automated test equipment (ATE), the automated test equipment comprises an antenna device according to one of the preceding claims, wherein the automated test equipment is configured to test a device under test, e.g. a wireless device under test; e.g. an antenna-in package device under test, using the antenna device.

The automated test equipment according to this embodiment is based on the same considerations as an antenna device described above. Moreover, this disclosed embodiment may optionally be supplemented by any other features, functionalities and details disclosed herein in connection with the antenna device, both individually and taken in combination.

An embodiment according to the invention creates an automated test equipment, wherein the automated test equipment comprises a device under test socket and one or more, e.g. blind mating, high frequency connectors, e.g. waveguide connectors, e.g. for establishing a high frequency connection with the antenna device, wherein the one or more high frequency connectors are arranged beside the test socket.

The automated test equipment according to this embodiment is based on the same considerations as an antenna device described above. Moreover, this disclosed embodiment may optionally be supplemented by any other features, functionalities and details disclosed herein in connection with the antenna device, both individually and taken in combination.

According to an embodiment, the test socket and the one or more high frequency connectors are arranged such that one or more external connections of the antenna device mate with the one or more high frequency connectors and such that a cover of the antenna device pushes the device under test into the device under test socket when the one or more external connections of the antenna device mate with the one or more high frequency connectors.

### BRIEF DESCRIPTION OF THE DRAWINGS

The accompanying drawings, which are incorporated in and form a part of this specification, illustrate embodiments of the invention and, together with the description, serve to explain the principles of the invention:

FIG. 1 is a diagram depicting an antenna device according to embodiments of the present invention.

FIG. 2A is a diagram depicting an antenna device in the disassembled state according to embodiments of the present invention.

FIG. 2B is a diagram depicting the antenna device of FIG. 2A in the assembled state according to embodiments of the present invention.

FIG. 2C is a diagram depicting a sectional view of the antenna device of FIG. 2A in the assembled state according to embodiments of the present invention.

FIG. 3A is a diagram depicting an antenna device in the assembled state according to embodiments of the present invention.

FIG. 3B is a diagram depicting the antenna device of FIG. 3A without the top metal plate according to embodiments of the present invention.

FIG. 3C is a diagram schematically depicting the antenna device of FIG. 2A according to embodiments of the present invention.

FIG. 4A is a diagram depicting an antenna device according to embodiments of the present invention.

FIG. 4B is a diagram depicting a back view of the antenna device of FIG. 4A according to embodiments of the present invention.

FIG. 4C is a diagram depicting an increased sectional view of the antenna device of FIG. 4A according to embodiments of the present invention.

FIG. 4D is a diagram schematically depicting an increased sectional view of the antenna device of FIG. 4A according to embodiments of the present invention.

FIG. 5A is a diagram depicting an antenna device according to embodiments of the present invention.

FIG. 5B is a diagram depicting the antenna device of FIG. 5A in the housing according to embodiments of the present invention.

FIG. 5C is a diagram depicting the antenna device of FIG. 5B in the disassembled state according to embodiments of the present invention.

FIG. 5D is a diagram depicting the antenna device of FIG. 5A in the operational state according to embodiments of the present invention.

FIG. 6A is a diagram depicting antenna simulation results of an antenna device according to embodiments of the present invention.

FIG. 6B is a diagram depicting antenna simulation results of an antenna device according to embodiments of the present invention.

FIG. 7A is a diagram depicting an automated test equipment for testing a wireless device under test, such as an antenna-in package, according to embodiments of the present invention.

FIG. 7B is a diagram depicting an automated test equipment for testing a wireless device under test disposed in a socket according to embodiments of the present invention.

### DETAILED DESCRIPTION

Reference will now be made in detail to several embodiments. While the subject matter will be described in conjunction with the alternative embodiments, it will be understood that they are not intended to limit the claimed subject matter to these embodiments. On the contrary, the claimed subject matter is intended to cover alternative, modifications, and equivalents, which may be included within the spirit and scope of the claimed subject matter as defined by the appended claims.

Furthermore, in the following detailed description, numerous specific details are set forth in order to provide a thorough understanding of the claimed subject matter. However, it will be recognized by one skilled in the art that embodiments may be practiced without these specific details or with equivalents thereof. In other instances, well-known methods, procedures, components, and circuits have not been described in detail as not to unnecessarily obscure aspects and features of the subject matter.

Some portions of the detailed description are presented in terms of procedures, steps, logic blocks, processing, and other symbolic representations of operations on data bits that can be performed on computer memory. These descriptions and representations are the means used by those skilled in the data processing arts to most effectively convey the substance of their work to others skilled in the art. A procedure, computer-executed step, logic block, process, etc., is here, and generally, conceived to be a self-consistent sequence of steps or instructions leading to a desired result. The steps are those requiring physical manipulations of physical quantities. Usually, though not necessarily, these quantities take the form of electrical or magnetic signals capable of being stored, transferred, combined, compared, and otherwise manipulated in a computer system. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the following discussions, it is appreciated that throughout, discussions utilizing terms such as “accessing,” “writing,” “including,” “storing,” “transmitting,” “associating,” “identifying,” “encoding,” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

### High Bandwidth Antenna Device for Ota Device Testing and Measurement

Embodiments of the present invention provide a novel antenna device for OTA testing and measurement using an antenna disposed in a socket of automatic test equipment (ATE) that provides high bandwidth for device testing and measurement. The antenna device can include a printed circuit board (PCB) having an opening with at least two probes disposed on or in the printed circuit board orthogonally (e.g., at 90 degrees) to each other, and a cavity between the portion of the PCB carrying the probes and a waveguide backshort. The cavity forms a dual-polarized waveguide between the portion of the PCB carrying the probes and the waveguide backshort, which is typically a reflective termination placed at the end of the waveguide. According to some embodiments, the opening in the printed circuit board is formed around the center of the cavity, and the cavity has a depth of a quarter wavelength, λ/4, plus an integer multiple of a half wavelength, within a tolerance of +/− 1/16 of the wavelength.

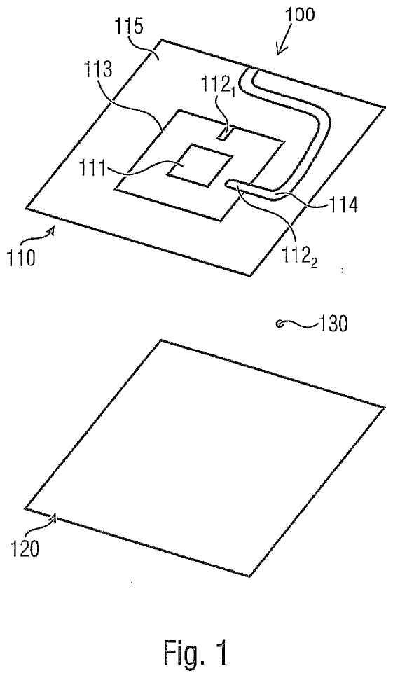

FIG. 1 depicts an exemplary antenna device 100 for performing OTA device testing and/or measurement according to embodiments of the present invention. The antenna device 100 includes a printed circuit board 110 including a gap or opening 111 and at least two probes 112 disposed in the printed circuit board orthogonally to each other. Opening 111 can be substantially square in shape. Although the example of FIG. 1 depicts two orthogonal probes 112, four probes forming two orthogonal pairs can be disposed in or on the printed circuit board 110. The antenna device 100 further includes a backshort 120, which may be formed by a metal base plate or by one or more layers of a multi-layered PCB, for example.

As depicted in FIG. 1, antenna device 100 includes a cavity 130 between the portion of the PCB 110 carrying the probes 112, which can be an aperture cutout or a plurality of layers of the PCB 110 carrying the probes 112, and the backshort 120. The cavity 130 may have, for example, a substantially rectangular cross-section or a squared cross section. The cavity 130 forms a waveguide between the portion of the PCB 110 carrying the probes 112 and the backshort 120, e.g., waveguide backshort 120. The opening 111 in the printed circuit board 110 is disposed around the center of cavity 130. According to some embodiments, cavity 130 has a depth of a quarter wavelength λ/4, which can be a guided wavelength in the waveguide formed by the cavity, plus an integer multiple of a half wavelength, wherein the integer may be zero or greater than zero. The wavelength is typically set according to the center frequency of antenna device 100.

The probes 112 are disposed on (or in) the printed circuit board 110, in an area 113 of the printed circuit board 110 surrounding the cavity 130 such that the probes 112 couple with modes (e.g., resonant electromagnetic field patterns) of cavity 130. The probes 112 form an orthogonal pair of probes 112 configured to excite at least two orthogonal modes of the waveguide. The probes 112 are coupled to at least two microstrip lines 114 formed on (or within) printed circuit board 110 in area 115 of the printed circuit board 110, which does not surround the cavity 130. The microstrip lines 114 form feeding networks of the probes, which are, for example, coupled to ports via transmission lines. In an embodiment, the feeding networks of the probes 112 can be coupled to respective differential ports via respective differential line transitions, according to embodiments.

The feeding networks of one or more of the probes 1121 having a first orientation and the feeding networks of one or more of the probes 1122 having a second orientation orthogonal to the first orientation, are disposed on different (e.g., opposing) layers of the printed circuit board 110. A ground layer may be disposed in between layers of PCB 110 such that the ground layer shields the different feeding networks. However, it should be noted that the antenna device 100 may optionally include additional components and functionalities disclosed herein, either individually or taken in combination.

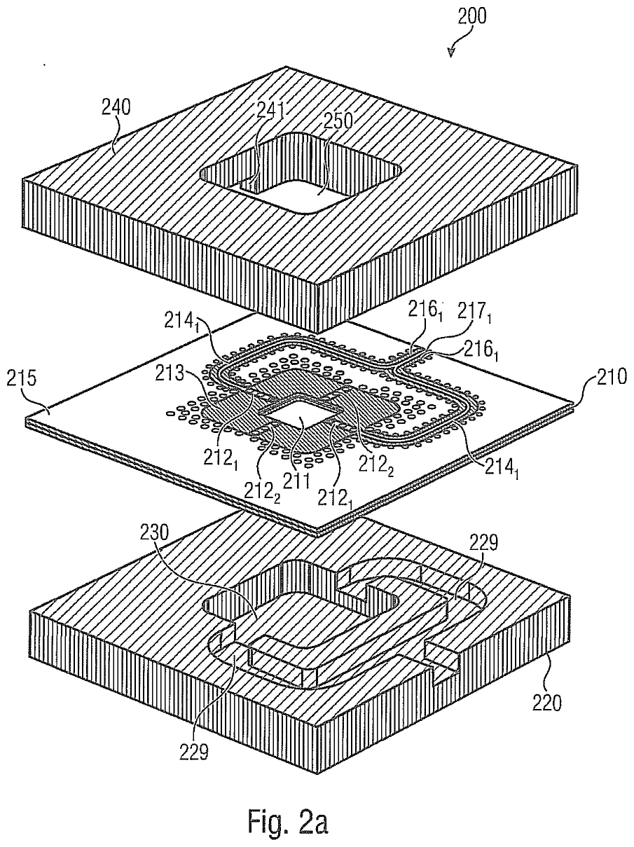

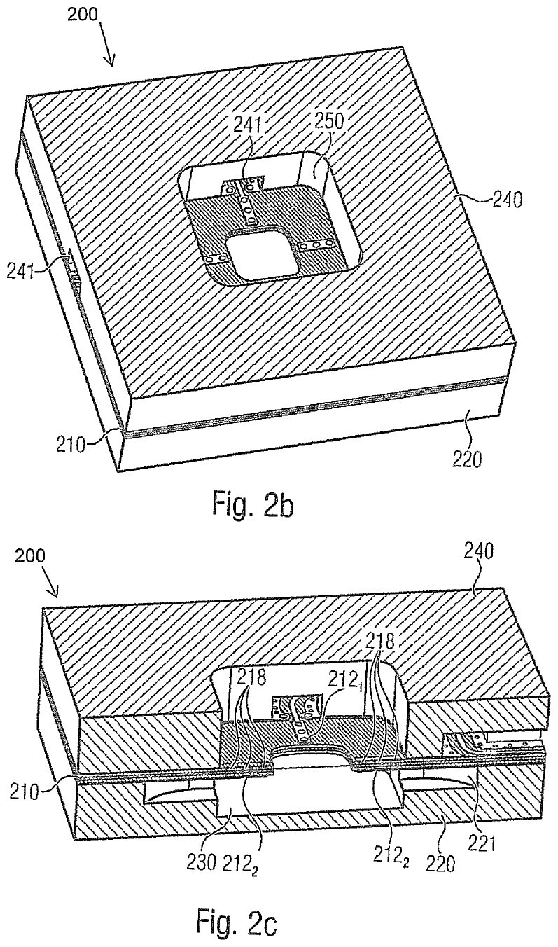

FIGS. 2A-2C depict an exemplary antenna device 200 for OTA testing and measurement using an ATE in a disassembled state according to embodiments of the present invention. As depicted in FIG. 2A, the antenna device 200 includes a printed circuit board 210 having an opening 211 and four probes 212 positioned as two orthogonal pairs. The opening 211 is a through hole substantially square in shape that functions to increase antenna bandwidth.

The antenna device 200 includes a backshort 220 formed by a metal base plate. The printed circuit board 210 is placed on or attached to the top surface of the metal base plate, and a cavity 230 is formed in an upper part of the metal base plate. The metal base plate helps to form the waveguide backshort 220. Cavity 230 can be substantially the same shape as opening 211.

Antenna device 200 includes cavity 230 between the portion of the PCB 210 carrying the probes 212 (e.g., an aperture cutout) and the backshort 220. In the example of FIGS. 2A-2C, cavity 230 has a squared cross section, although the cavity 230 may have a substantially rectangular cross section, a substantially circular cross section, or a substantially oval cross section, according to embodiments. In the example of FIG. 2A, cavity 230 forms a waveguide between the portion of the PCB 210 carrying the probes 212 and the waveguide backshort 220. The opening 211 of the printed circuit board 210 is disposed around a central axis of the cavity 230. According to some embodiments, cavity 230 has a depth of a quarter wavelength 24, e.g., a guided wavelength in the waveguide formed by the cavity, plus an integer multiple of a half wavelength, where the integer may be zero or greater. The wavelength is typically set according to the center frequency of antenna device 200.

The probes 212 are positioned as two orthogonal pairs disposed on the printed circuit board 210 in area 213 of the printed circuit board 210 surrounding cavity 230 between the printed circuit board 210 and the waveguide backshort 220. The probes couple with electromagnetic modes of cavity and are configured to excite main orthogonal modes, TE₁₀ and TE₀₁, of the waveguide.

The four probes 212 are coupled to respective microstrip lines 214 on the printed circuit board 210 in area 215 of the printed circuit board 210, which does not surround the cavity 230. Two probes 2121 have a first orientation and represent two collinear probes. The two probes 2121 can be coupled to a first differential port 2171 using respective microstrip lines 2141 and differential line 2161. The two other collinear probes 2122 have a second orientation orthogonal to the first orientation and can be coupled to a second differential port 2172 using respective microstrip lines 2142 and differential line 2162. Advantageously, the differential feeding provides symmetry to antenna device 200, increases decoupling between orthogonal probes, and increases operational bandwidth. The differential transmission lines may include shielding, according to embodiments.

Metal base plate 220 accommodates the microstrip lines 2142 and differential line 2162, e.g., via channels 229 formed on an upper portion of the metal base plate 220 corresponding to the microstrip lines 2142 and differential transmission lines 2162. The metal base plate 220 can also include a cutout or opening corresponding to the location of the second differential port 2172.

The feeding networks of the two probes 2121 have a first orientation and the feeding networks of the two probes 2122 have a second orientation, which is orthogonal to the first orientation, and are disposed on opposite layers of the printed circuit board 210, with a ground layer optionally disposed in between the layers to shield the different feeding networks. This arrangement of the feeding networks (on the opposite layers of the PCB 210) advantageously provides convenient routing and a high degree of isolation, and greatly simplifies the PCB layout as a blind or buried via is not necessary. The feeding networks are coupled to differential lines 216 with 100 Ohm differential interfaces, according to some embodiments, which offer tremendous versatility when antenna circuit 200 is integrated with transceiver chain components on the same PCB.

According to some embodiments, cavity 230 has a width of a half wavelength A/2. The probes 212 have an electrical length that is substantially equal to the depth of the cavity, e.g., within a tolerance of 1/16 of the wavelength. For example, the length of the probes may be selected according to the particular dielectric of PCB. For example, if alumina substrate is used, the probes can be relatively short (e.g., shorter than the depth of the cavity). However, the electrical length (as measured in wavelengths), can be considered approximately the same for different materials.

The antenna device 200 further includes an upper metal plate 240 and an additional waveguide portion 250 which is formed in the upper metal plate 240 such that the additional waveguide portion 250 functions as an extension of the waveguide formed by the cavity 230. The upper metal plate may include channels on a bottom part of the upper metal plate 240 corresponding to the microstrip lines 2141 and differential line 2161, for example. The upper metal plate 240 may also include a cutout or opening, e.g., cutout 241 depicted in FIG. 2B, which corresponds to the first differential port 2171. The printed circuit board 210 is disposed between the metal base plate 220 and the upper metal plate 240. As will be depicted in the following figures, the printed circuit board 210 is disposed between the metal base plate 220 and the upper metal plate 240.

The antenna device may include, for example, one or more external connections, such as blind mating waveguide connections, where a first external connection is coupled with one or more of the probes having a first orientation, and/or wherein a second external connection is coupled with one or more probes having a second orientation, which may be orthogonal to the first orientation. The one or more external connections may be, for example, waveguide connections, and the one or more external connections may be, for example, blind mating connections, e.g., blind-mating waveguide connections. The one or more external connections may be aligned in the same direction as the main radiation direction of the antenna device 200.

FIG. 2B depicts the antenna device of FIG. 2A in an assembled state according to embodiments of the present invention. As depicted in FIG. 2B, the PCB 210 is disposed between or pressed between the metal base plate 220 and the upper metal plate 240. The cavity 230 (FIG. 2C) and corresponding waveguide are not shown in FIG. 2B as the cavity 230 is disposed in the top part of the waveguide backshort 220 and covered by the PCB 210 and the top plate 240. In the example of FIG. 2B, the additional waveguide portion 250 is formed in the upper metal plate 240.

Cutouts 241 are formed in the bottom part of the upper metal plate 240, with one cutout on each of the two lateral sides of the upper metal plate 240. The cutouts 241 are disposed above the respective microstrip lines 2141 disposed on the upper part of the printed circuit board 210 in area 215 of the printed circuit board 210, which does not surround cavity 230. The cutouts have substantially rectangular form in this example.

FIG. 2C depicts a sectional view of antenna device 200 in an assembled state for OTA testing and measurement using an ATE according to embodiments of the present invention. As depicted in FIG. 2C, PCB 210 includes multiple layers. The printed circuit board 210 may include multiple layers (e.g., three or four layers), and the probes 212 extend to or pass through several PCB layers coupled through probe vias 218.

The cavity 230 is depicted in FIG. 2C in the top part of the waveguide backshort 220 disposed between the waveguide backshort 220 and the PCB 210. An additional cutout 221 is disposed on the upper part of the waveguide backshort 220. The additional cutout 221 may, for example, have a depth at least 50% smaller than the depth of the cavity 230, although there is no strict requirement. Preferably the depth is selected such that it does not have an impact on transmission line impedance. The additional cutout 221 is formed to accommodate the respective microstrip lines 2142 and the two further differential transmission lines 2162, which couple the probes 2122 to a second differential port 2172.

The cavity 230 may, for example, have a substantially square cross section. The cavity 230 forms a waveguide between the portion of the PCB 210 carrying the probes 212 and the waveguide backshort 220. The opening 211 on the printed circuit board 210 is disposed in a central area around cavity 230. The cavity 230 has a depth of a quarter wavelength 24, e.g., of a guided wavelength in the waveguide formed by the cavity, plus an integer multiple of a half wavelength, where the integer is zero or greater. The wavelength is typically set at the center frequency of antenna device 200.

It should be noted that the antenna device 200 may optionally include any of the components and functionalities disclosed herein, either individually or taken in combination.

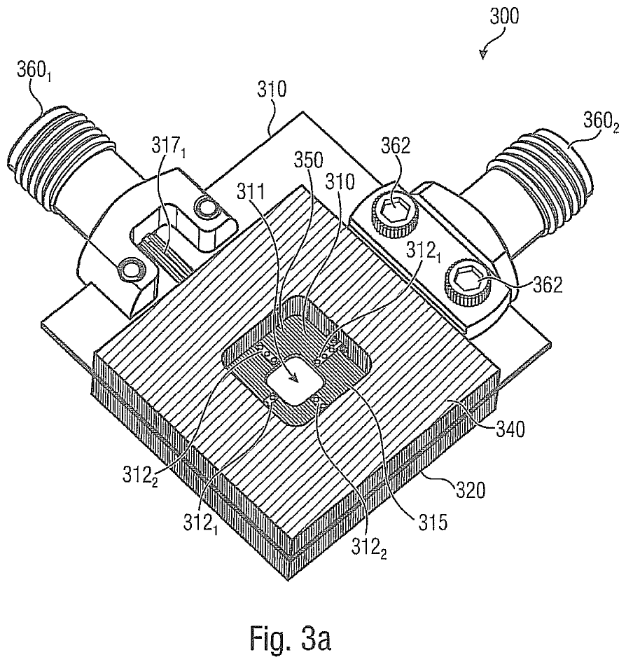

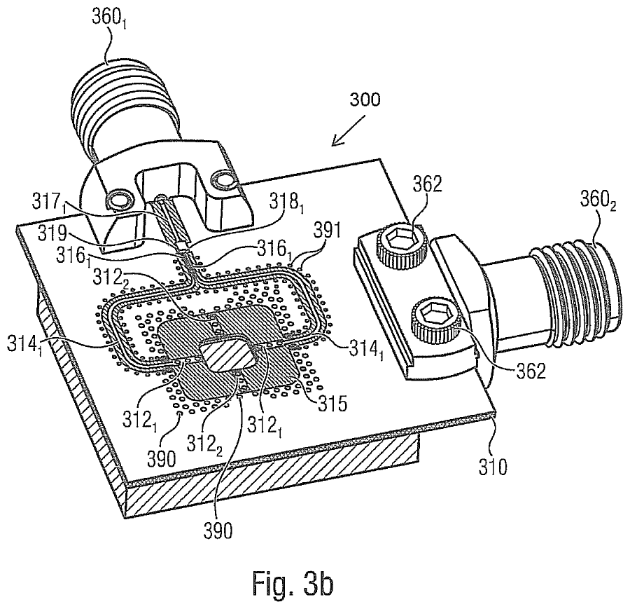

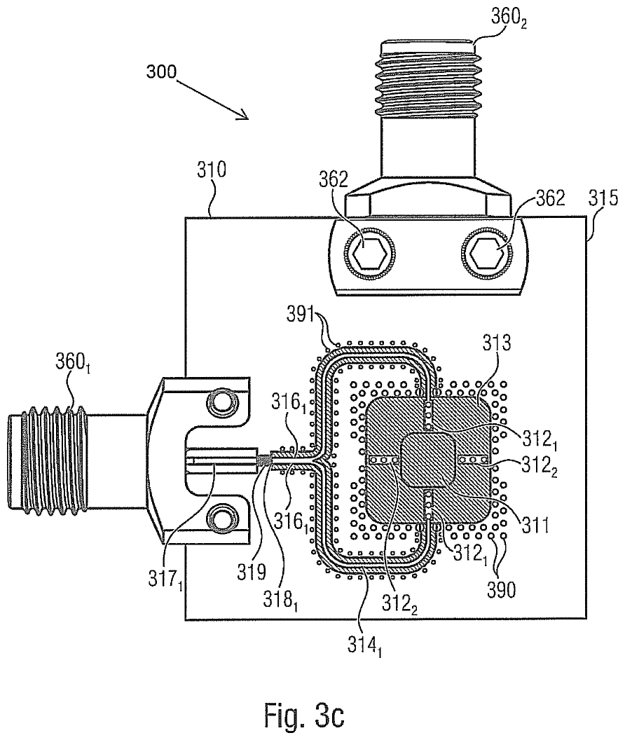

FIGS. 3A-3C depict an exemplary antenna device 300 according to embodiments of the present invention. FIG. 3A depicts antenna device 300 for OTA testing and measurement using an ATE in an assembled state according to embodiments of the present invention. The antenna device 300 includes a printed circuit board 310 including an opening 311 and four probes 312, which are positioned as two orthogonal pairs. The opening 311 is a substantially square hole. The opening 311 may be substantially rectangular, circular, or oval-shaped according to embodiments. The opening 311 functions as a through hole that advantageously increases antenna bandwidth.

According to some embodiments, the antenna device 300 includes a backshort 320 formed by a metal base plate. Printed circuit board 310 is disposed on or attached to a metal base plate, and a cavity (not depicted) is formed in an upper part of the metal base plate. The metal base plate also forms the waveguide backshort 320.

In the example of FIG. 3A, the antenna device 300 further includes an upper metal plate 340, and an additional waveguide portion 350 is formed in the upper metal plate 340 and functions as an extension of the waveguide formed by the cavity (not depicted). The printed circuit board is disposed between the metal base plate 320 and the upper metal plate 340.

Four probes 312 are coupled to respective microstrip lines under the upper metal plate 340 on the printed circuit board 310 in area 315 of the printed circuit board 310, which does not bound the cavity. Two probes 3121 are collinear and have a first orientation. The two probes 3121 are coupled to a first port (e.g., via coaxial connector 3601) using a microstrip line 3171, which may partially extend under the upper metal plate 340, using differential line 3161 under the upper metal plate 340 and microstrip lines 3141. According to some embodiments, a balun 319 (not depicted in FIG. 3A) is disposed between the microstrip line 3171 and the differential lines 3161. Two collinear probes 3122 have a second orientation orthogonal to the first orientation and are coupled to a second port (e.g., in the form of a coaxial connector 3602) using a microstrip line, using differential lines (not depicted) and respective microstrip lines (not depicted). A balun (not depicted) can be disposed in between the microstrip line and the differential lines. Advantageously, differential feeding provides symmetry to antenna circuit, increases decoupling between orthogonal probes, and increases operational bandwidth. The differential transmission lines may include shielding according to embodiments.

In the example of FIG. 3A, PCB 310 extends beyond the metal base plate 320 and the upper metal plate 340; however, the metal plate 320 and PCB 310 can vary in size depending the device to be tested. Two coaxial connectors 360 are mounted on the PCB 310. A first coaxial connector 3601 can couple a first microstrip line 3171 to a measurement instrument, and a second coaxial connector 3602 can couple a second microstrip line (not depicted) to a measurement instrument.

FIG. 3B depicts antenna device 300 in the assembled state without the top metal plate 340 according to embodiment of the present invention. As depicted in FIG. 3B, the printed circuit board 310 includes opening 311 and the four probes 312, which are positioned as two orthogonal pairs. The four probes 312 are coupled with respective microstrip lines 314 on the printed circuit board 310 in area 315 of the printed circuit board 310, which does not surround the cavity 330. Two collinear probes 3121 have a first orientation and are coupled to a first differential port 3181 using respective microstrip lines 3141 and using differential line 3161. Two collinear probes 3122 have a second orientation orthogonal to the first orientation. The two probes 3122 are coupled to a second differential port (not seen) using respective microstrip lines (not depicted) using an additional differential line (not depicted). Differential feeding provides symmetry to antenna circuit, increases decoupling between orthogonal probes and increases operational bandwidth. The differential transmission lines may include shielding according to embodiments.

In the example of FIG. 3B, first differential port 3181 is coupled to a microstrip line 3171 via a balun 319. The microstrip line 3171 is coupled to the first coaxial connector 3601 thereby coupling the first differential port 3181 to a corresponding measurement instrument. The second coaxial connector 3602 is disposed upside down in relation to the first coaxial connector 3601 and is operable to couple the second differential port disposed on the bottom surface of the PCB 310 to a corresponding measurement instrument.

The first and second coaxial connectors 360 are disposed on or attached to the sides of the PCB 310 by screws 362. The first and second coaxial connectors 360 are attached upside down to each other and rotated by 180 degrees. Plated vias (e.g., through holes) 390 form sidewalls of the backshort 320 and of the cavity 330. The cavity sidewalls or waveguide sidewalls of the cavity 330 are implemented using vias 390 extending through the multi-layer printed circuit board 310. The vias may include plated through via holes which may extend through a plurality of layers of the PCB 310. Via holes 391 can be plated and provide shielding for the respective microstrip lines.

FIG. 3C depicts PCB 310 of the antenna device 300 and the coaxial connectors 360 from a top view according to embodiments of the present invention. As depicted in FIG. 3C, the antenna device 300 includes a printed circuit board 310 that includes an opening 311 and four probes 312 positioned as two orthogonal pairs.

The probes 312 are positioned as two orthogonal pairs on the printed circuit board 310 in area 313 of the printed circuit board 310 surrounding the cavity 330 between the printed circuit board 310 and the waveguide backshort 320 so that the probes couple with electromagnetic modes of the cavity. The four probes 312 are coupled with respective microstrip lines 314 on the printed circuit board 310 in an area 315 of the printed circuit board 310, which does not bound the cavity 330. The two probes 3121 are coupled to a first differential port 3181 using respective microstrip lines 3141 and using differential line 3161. Two probes 3122 have a second orientation and represent two further collinear probes. It should be noted that the differential line portion 316 is bounded by (e.g., disposed in between) balun 319 and the junction of microstrip feeding lines 3141.

The feeding networks of the two probes 3121 and the feeding networks of the two probes 3122 are disposed orthogonally on opposite layers of the printed circuit board 310, e.g., with a ground layer in between, such that the ground layer shields the different feeding networks. Placing the feeding networks on the opposite layers of the PCB 310 provides ease of routing and relatively high isolation. Advantageously, this arrangement simplifies PCB design significantly, since no blind or buried via is necessary.

A plurality of plated through via holes 390 forms sidewalls of the backshort 320 and correspondingly of the cavity 330. The boundaries, e.g., sidewall boundaries, of the cavity 330 are implemented using vias 390 through the multi-layer printed circuit board 310, e.g., using plated through via holes which may, for example, extend through a plurality of layers of the PCB 310. Via holes 391 may be plated and shield the respective microstrip lines.

It is noted that the antenna device 300 may optionally include any of the features, functionalities and details disclosed herein, both individually or taken in combination.

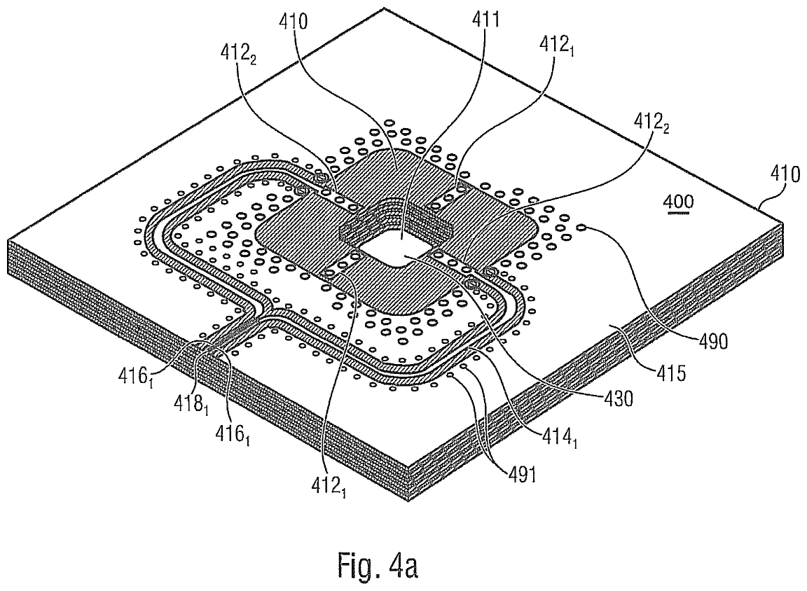

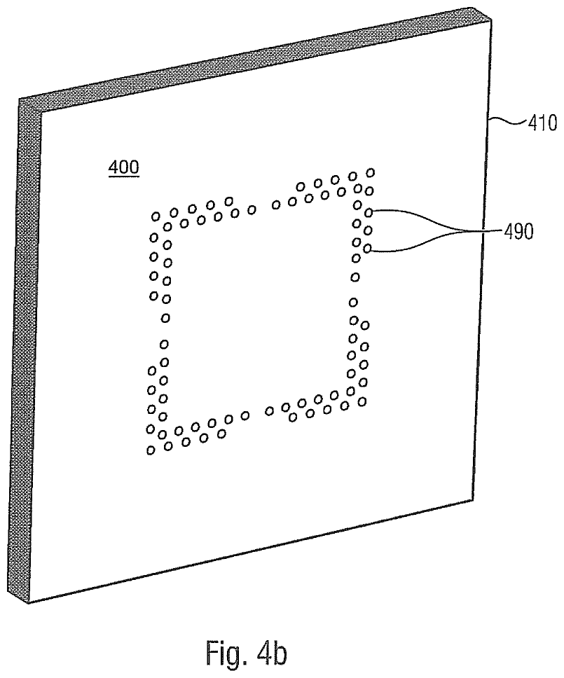

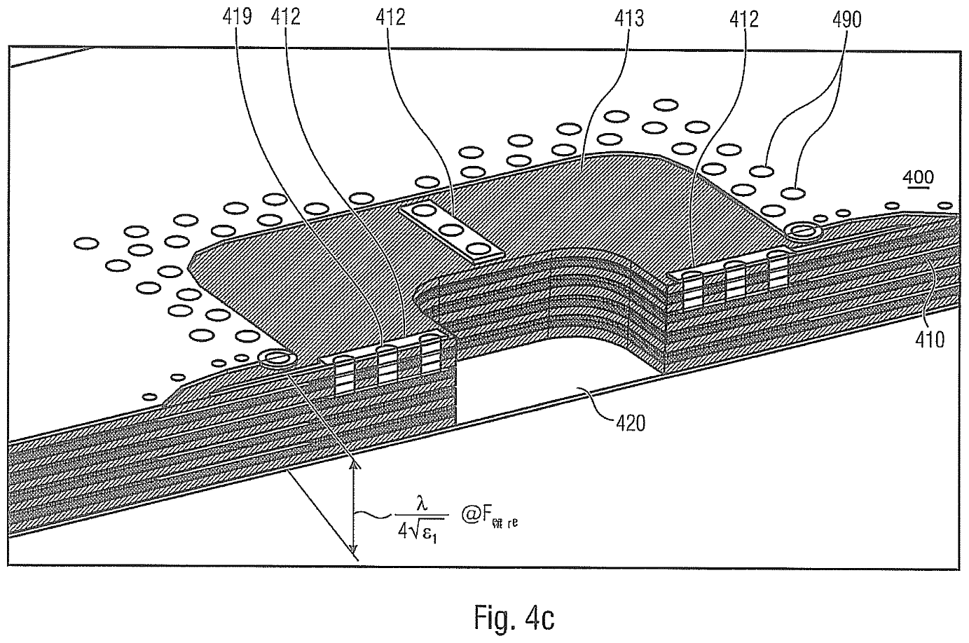

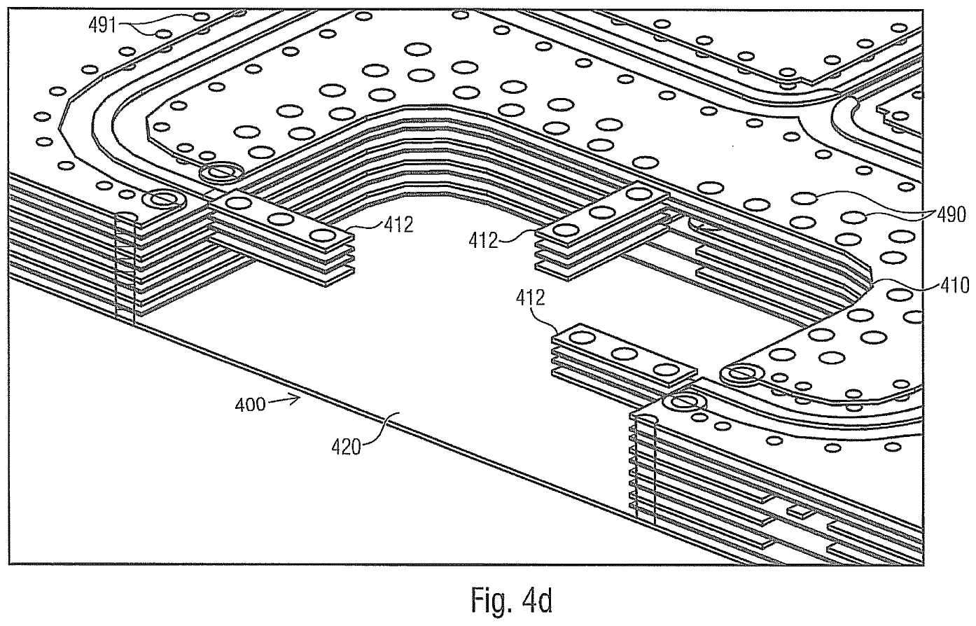

FIGS. 4A-4D depict an exemplary antenna device 400 including a PCB having a thickness selected based on the dielectric permittivity of the PCB substrate (dielectric) material according to embodiments of the present invention. As depicted in FIG. 4A, the antenna device 400 includes a printed circuit board 410 including an opening 411 and four probes 412 positioned as two orthogonal pairs. The opening 411 has a substantially square hole that advantageously increases antenna bandwidth.

The printed circuit board 410 can be a relatively thick multi-layer (e.g., more than 8 layers) printed circuit board. The waveguide backshort 420 is implemented using a layer, e.g., a metal layer, of the printed circuit board. The bottom PCB layer serves as a metal backshort 420.

The PCB 410 has a thickness defined as:

$$∼ \frac{λ}{4 \sqrt{{ε}_{r}}} @ {F}_{center} ,$$

where εᵣ is the dielectric permittivity of the PCB substrate (dielectric) material.

The antenna device 400 includes the cavity 430 located between a portion of the PCB 410 carrying the probes 412, namely an aperture cutout, and the backshort 420. The cavity 430 may, for example, have a substantially square cross section. The cavity 430 forms a waveguide between the portion of the PCB 410 carrying the probes 412 and the waveguide backshort 420. The opening 411 in the printed circuit board 410 is formed in a central area around the central axis of the cavity 430. The cavity 430 has a depth of a quarter wavelength 24 (e.g., the guided wavelength in the waveguide formed by the cavity) in the PCB substrate material divided by Ver plus an integer multiple of a half wavelength. The integer may be zero or greater than zero, and the wavelength is typically set at the device's center frequency.

The boundaries, e.g., sidewall boundaries, of the cavity 430 are formed by vias 490 through the multi-layer printed circuit board 410, e.g., using plated through via holes that extend through a plurality of layers of the PCB 410.

As shown in FIGS. 4A to 4D, plated through via holes 490 form sidewalls of the backshort 420 and the cavity 430. The boundaries, e.g., sidewall boundaries, of the cavity 430 are implemented using vias 490 through the multi-layer printed circuit board 410, e.g., using plated through via holes which can extend through a plurality of layers of the PCB 410. A plurality of through via holes 491 form shielding of the respective microstrip lines, as could be seen in FIGS. 4A, 4C and 4D.

As depicted in FIGS. 4A, 4C and 4D, the probes 412 are positioned in two orthogonal pairs on the printed circuit board 410 in area 413 surrounding the cavity 430 between the printed circuit board 410 and the waveguide backshort 420. The probes are operable to couple with modes of cavity which are configured to excite main orthogonal modes, TE₁₀ and TE₀₁, of the waveguide.

The four probes 412 are coupled with respective microstrip lines 414 on the printed circuit board 410 in area 415 of the printed circuit board 410 which does not surround the cavity 430. Two collinear probes 4121 have a first orientation and are coupled to a first differential port 4181 using respective microstrip lines 4141 and differential line 4161. Collinear probes 4122 have a second orientation orthogonal to the first orientation and are coupled to a second differential port using respective microstrip lines and using further differential line (not depicted). Differential feeding advantageously provides symmetry to antenna circuit, increases decoupling between orthogonal probes, and widens operational bandwidth. The differential transmission lines may be shielded according to embodiments.

As depicted in FIG. 4C, probes 412 extend through several PCB layers of the thick PCB coupled through probe vias 419. The probes 412 connect the upper layer of the PCB layer, and typically utilize at least three PCB layers. For example, at least three upper PCB layers can be coupled through the probe vias 419 in the example of FIG. 4C. According to some embodiments, not all PCB layers are utilized by the probes 412, or the probes 412 may, for example, utilize less than a half of the PCB layers. However, it should be noted that the number of layers utilized by the probes depends on the amount of antenna bandwidth required, and at least one or two of the layers including metal layers. The probes can be disposed inside internal layers without utilizing the top layer, according to embodiments.

It should be noted that the antenna device 400 may optionally include any of the components and functionalities disclosed herein, either individually or taken in combination.

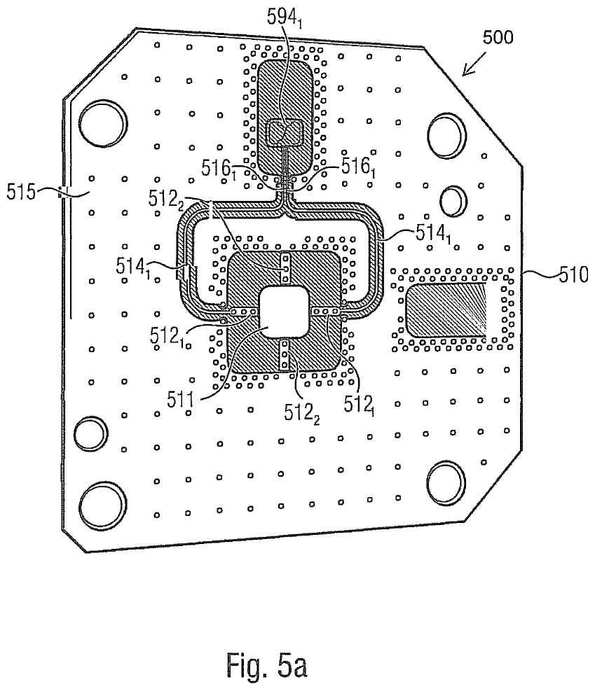

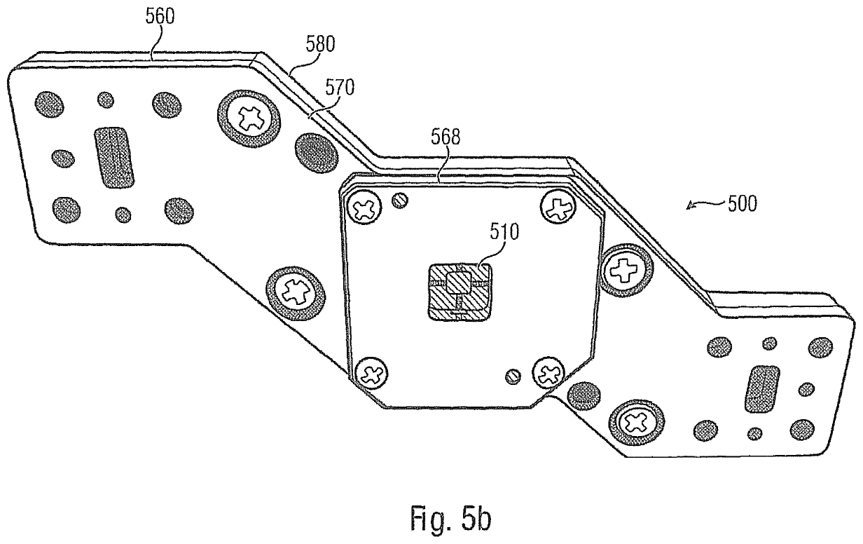

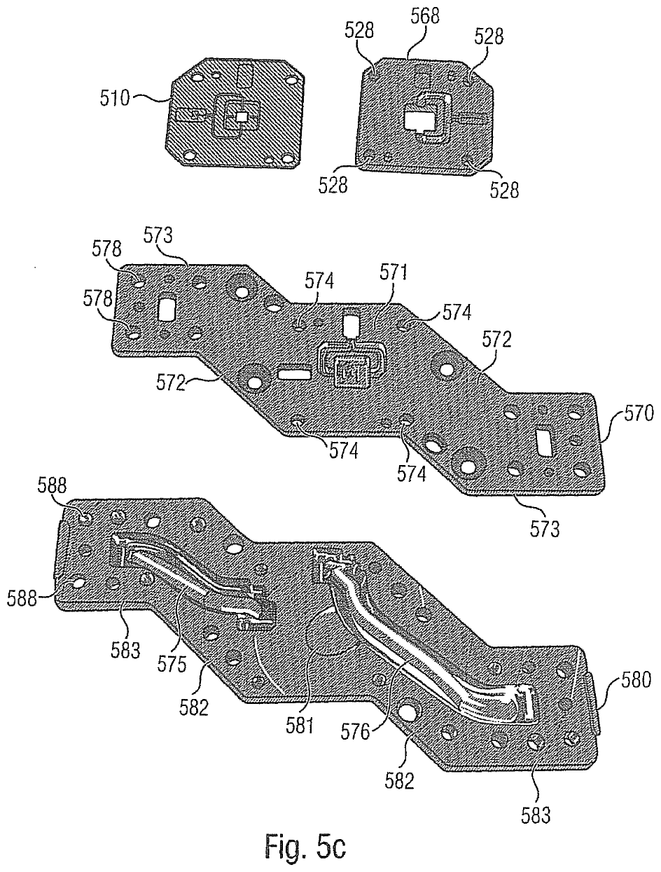

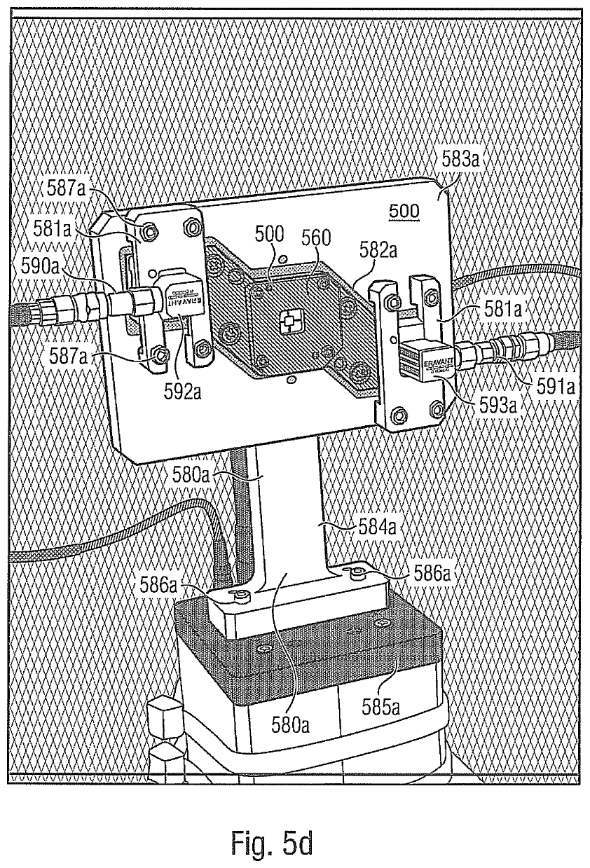

FIGS. 5A-5D depict an exemplary antenna device 500 including a metal housing for OTA device testing and measurement using ATE according to embodiments of the present invention. FIG. 5A depicts a printed circuit board 510 including an opening 511 and four probes 512 positioned as two orthogonal pairs. Opening 511 is a substantially square though hole for increasing antenna bandwidth. Although the opening 511 is depicted as substantially square, the opening 511 may be substantially rectangular, circular, oval shaped, or in the shape of an X or cross, according to embodiments, although any other suitable shape can be used.

The four probes 512 are coupled with respective microstrip lines 514 on the printed circuit board 510 in area 515 of the printed circuit board 510, which does not surround the cavity 530. Two probes 5121 have a first orientation and are coupled to a first (e.g., differential) waveguide transition 5941 using respective microstrip lines 5141 and differential lines 5161. Two collinear probes 5122 have a second orientation orthogonal to the first orientation. The two probes 5122 are coupled to a second (e.g., differential) waveguide transition using respective microstrip lines and an additional differential line (not depicted). Differential feeding provides symmetry to antenna circuit, increases decoupling between orthogonal probes and widens operational bandwidth. The differential transition lines may be shielded according to embodiments.

FIG. 5B depicts the antenna device 500 in the assembled state (ready to use) within a metal housing 560. A backshort of the antenna 500 is formed by a metal base plate (e.g., by plate 570 or plate 580) or by a layer (e.g., a bottom layer) of the printed circuit board. The printed circuit board 510 is disposed on or attached to metal base plate 570, and a cavity (not depicted) is formed in an upper part of the metal base plate 570. The metal base plate 570 also forms the waveguide backshort 520.

Separate components of the metal housing are depicted in FIG. 5C according to embodiments. An upper layer 568 of the metal base plate is depicted including mount holes 528 for accommodating screws configured to fix parts of the metal housing together. An additional waveguide portion is formed in the upper metal plate 568 as an extension of the waveguide formed by the cavity (not depicted). The printed circuit board 510 is disposed, e.g., pressed, between the upper metal plate 568 and the middle metal plate 570 of antenna 500.

In addition to the upper metal plate 568, the metal housing further includes two metal layers 570 and 580 (e.g., a middle metal layer and a lower metal layer), both having respective central parts 571, 581, and two pairs of respective peripherical parts 572, 573 and 582, 583. For example, central parts 571, 581 of the two metal layers 570, 580 substantially adhere to the form of the PCB 510 (e.g., an approximately rectangular, square, or polygonal form) and the upper metal plate 568. For example, the first peripherical parts 572, 582 of metal layers 570, 580 extend from two opposite sides of the central parts 571, 581 at an angle and form metal plates. For example, the second peripherical parts 573, 583 of the two metal layers 570, 580 extend at an angle from the first peripherical parts 572, 582 and form metal plates. The second peripherical parts 573, 583 are parallel to the central parts 571, 581. In this example, sides of the second peripherical parts 573, 583 are parallel to corresponding sides of the central parts 571, 581. Metal layer 570 includes mount holes 574 for mounting the upper metal plate 568 to the middle metal plate 570 and to the lower metal layer 580. The metal layers may, for example, also include alignment means, e.g., alignment pins or alignment holes. Lower metal layer 580 includes two waveguide structures 575, 576 for the first and second polarizations. For example, both metal layers 570, 580 include mount holes 578, 588 for fixing the antenna 500 in the metal housing and mount holes for attaching the antenna 500 in the metal housing 560 to the corresponding testing stand, mount, or test equipment.

FIG. 5D depicts the antenna device 500 in the assembled state, e.g., in the metal housing 560, and attached at a testing stand 580a. The testing stand has an upper part 583a and a below part 584a. The below part 584a stands on a stable base 585a and is attached to the stable base 585a with screws 586a. The parts of the metal housing 560 are, for example, fixed on the testing stand 580a with metal fixators 581a. The metal fixators 581a have an N-shape. The metal fixators 581a accommodate the second peripherical parts 573, 583 (or the entire antenna device 500) in a hollow cutout 582a of testing stand 580a. The hollow cutout 582a has a shape substantially corresponding to metal housing 560. The metal fixators 581a are attached to the upper part 583a of the testing stand 580a with screws 587a. In this example, each metal fixator 581a is attached with four screws 587a.

First and second coaxial connectors 590a, 591a are attached to waveguide transitions 592a, 593a which are operable to establish electromagnetic coupling with waveguide structures 575, 576, and the coaxial connectors are thereby coupled with the antenna 500 by the waveguide transitions 592a, 593a, the waveguide structures 575, 576 and transmission line traces (e.g., a waveguide coupling structure 5941, differential lines 5161 and microstrip lines 5141) on the printed circuit board 510. Accordingly, a first coaxial connector 590a is associated with a first polarization, and a second coaxial connector 591a is associated with a second polarization.

It should be noted that the antenna device 500 may optionally include any of the features, functionalities and details disclosed herein, both individually or taken in combination.

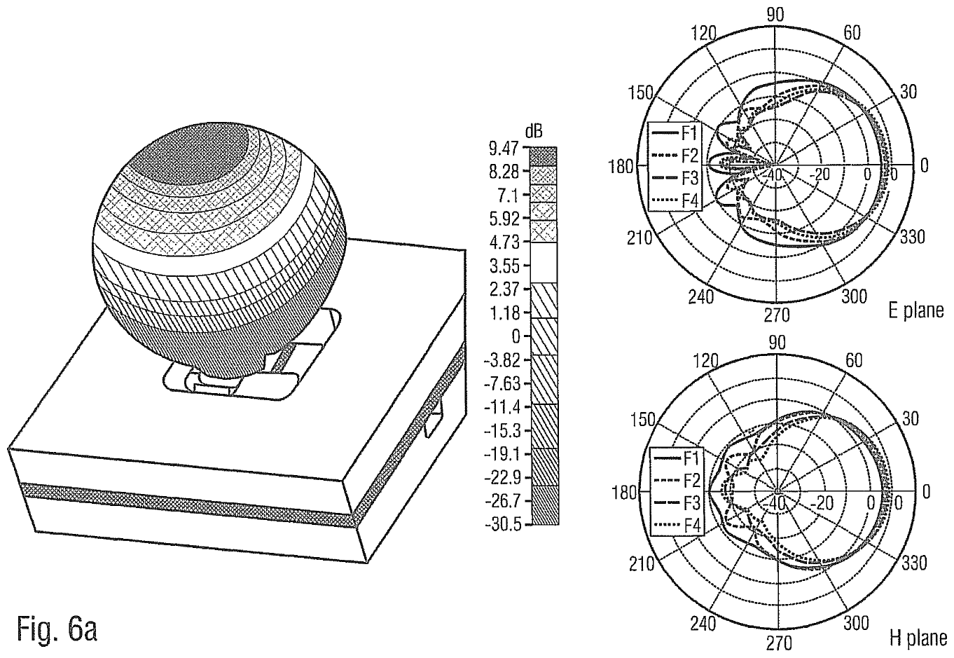

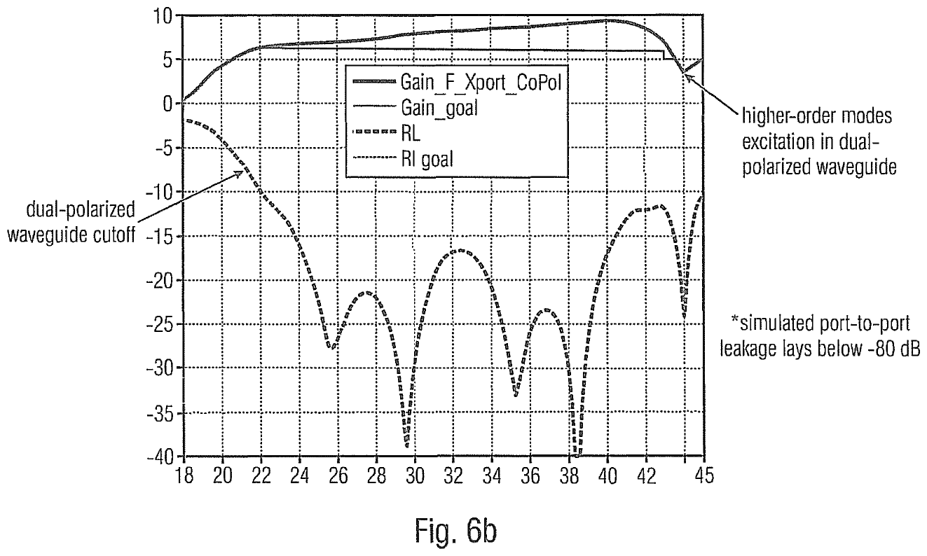

FIGS. 6A and 6B depict exemplary antenna simulation results of an antenna device according to embodiments of the present invention. Any of the antenna devices 100, 200, 300, 400 and 500, depicted in FIGS. 1-5D show performance similar to the results represented in FIGS. 6A and 6B.

FIG. 6A depicts an exemplary antenna 3D radiation pattern, as well as antenna radiation patterns in plane E (an electric field plane) and plane H (a magnetic field plane), at frequencies F₁=24.25 GHz, F₂=29.5 GHZ, F₃=37 GHz, F₄=40 GHz according to embodiments of the present invention. FIG. 6B depicts exemplary antenna boresight gain and antenna reflection coefficient dependencies over frequency according to embodiments of the present invention.

As depicted in FIGS. 6A and 6B, simulated electrical performance of the exemplary antenna devices described herein according to embodiments of the present invention can be characterized by:
1) Operational frequency band of 22-43 GHZ (65%) considering 10 dB RL;
2) Insertion loss in antenna circuit of the range between 0.75 and 1.35 dB over the frequency band (Megtron6-based board);
3) Antenna gain of the range between 6 and 9.5 dBi over the band;
4) Port-to-port leakage of less than-80 dB over the band; and
5) Cross-polarized component discrimination in far-field of higher than 55 dB over the band.

Moreover, the mechanical performance of the antenna devices can be characterized by:
1) Antenna circuit occupying only 2×220 area in PCB, where λ₀ is calculated at the center frequency of 32.5 GHz; and
2) Antenna PCB utilizing at least 3 layers, where its processing does not require blind or buried vias.

In the simulation depicted in FIGS. 6A and 6B, operational frequency band is 22-43 GHZ (65%) considering 10 dB RL. Insertion loss in antenna circuit is 0.75 . . . 1.35 dB over the frequency band (Megtron6-based board). Antenna gain is 6-9.5 dBi over the band. Port-to-port leakage is <−80 dB over the band. Cross-polarized component discrimination in far-field is >55 dB over the band.

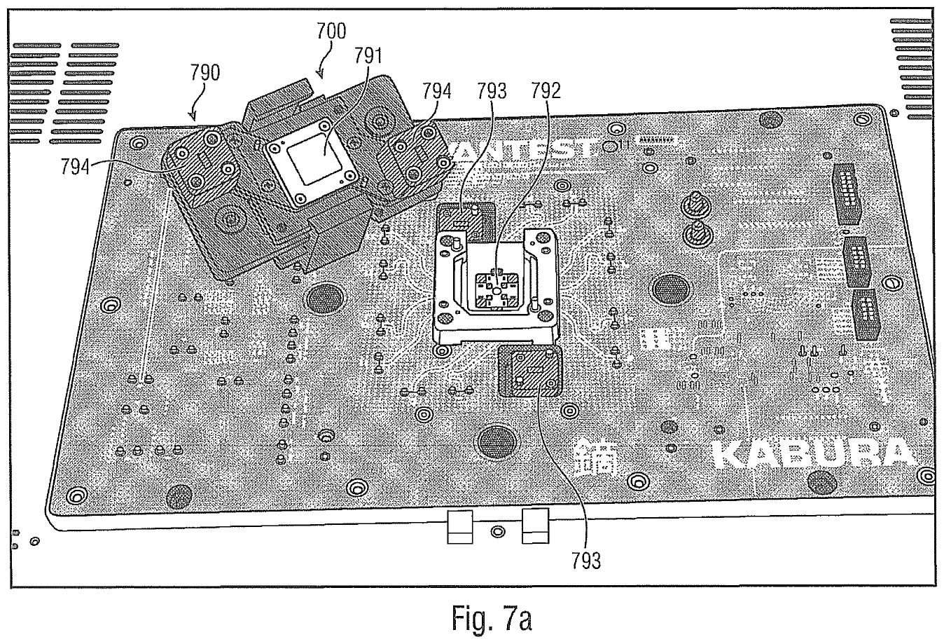

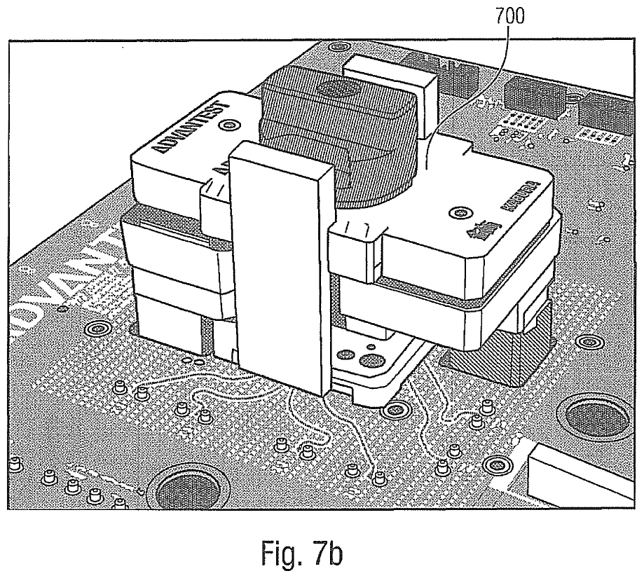

FIGS. 7A and 7B depict exemplary automated test equipment including an antenna device 700. The automated test equipment includes antenna device 700 and is configured to test a device under test (DUT) 792, e.g., a wireless device under test, such as an antenna-in package device under test, using the antenna device 700. The antenna-in package device under test can be a smartphone, for example.

The automated test equipment receives the device under test 792 in an electrical socket and includes blind mating connectors 793. Two blind mating connectors 793 are depicted in FIG. 7A, although the automated test equipment may include additional blind mating connectors 793 according to embodiments. The blind mating connectors 793 can be high frequency connectors, e.g., waveguide connectors, such as those depicted in FIG. 7A. The blind mating connectors 793 are operable to establish a high frequency connection with the antenna device 700. The connectors 793 are disposed beside a test socket in this example.

The antenna device 700, which can be an OTA measurement antenna, is disposed in a metal housing and fixed to socket lid 790. A pusher 791 is attached to the antenna device 700. The pusher 791 is made from a radio transparent material and is operable to push the device under test 792 into the electrical socket. The pusher 791 may be also configured as a cover of the antenna device 700 according to some embodiments.

Upon installation of the socket lid 790 on the automated test equipment, first and second waveguide connectors 794 interconnect with the blind mating waveguides 793. The blind mating waveguides 793 connect the measurement antenna millimeter wave signals to ATE measurement instrumentation.

The antenna device 700 includes two external connections 794, which can be waveguide connections. Although two external connections 794 are depicted in FIG. 7A, the antenna device 700 may also include one or more external connections 794. External connections 794 of the antenna device 700 couple with the connectors 793 and such that the pusher 791 of the antenna device 700 pushes the device under test 792 into the device under test socket when the connections 794 of the antenna device 700 mate with the connectors 793.

FIG. 7B depicts the antenna device 700 fixed to the automated test equipment. Automated test equipment 700 may optionally include any of the features and functionalities and details disclosed herein with respect to other embodiments.

According to some embodiments, the antenna devices described herein are used for integration in a socket for over the air (OTA) testing of antenna in package (AiP) modules for applications like 5G wireless communication and can be used for far-field and radiating near field OTA testing in an embodiment according to the invention. In an OTA test and measurement application, the requirements are different from a known antenna layout (or design) for a AiP antenna array, and it has been found that it is advantageous to use an antenna technology which is different from the antenna topology used on an AiP antenna array like a 5G module. This is because, in OTA applications, the measuring antenna is a single antenna element (not an antenna array), and the size of the antenna is not critical. Antenna gain is not critical because it is used on the radiating near-field (close to the DUT unlike a base station in a real OTA scenario), so it is important to have a large bandwidth to cover all the frequencies to be tested.

The exemplary antenna design (or antenna layout) depicted in FIGS. 2A to 2C includes a dual-polarized waveguide (230), a waveguide backshort (220) and PCB (210). Two orthogonal pairs of differentially fed microstrip probes (212) are disposed inside an aperture cutout area (211) so as they excite the main orthogonal modes of the waveguide (TE₁₀ & TE₀₁). Differential feeding helps to provide symmetry to antenna circuit, increases decoupling between orthogonal probes and widens operational bandwidth.

A probe's feeding networks are typically disposed on the opposite layers of the PCB for ease of routing and high isolation. This enables PCB process simplicity because no blind/buried via is needed. The feeding networks are coupled to differential lines or differential line transitions (216) with 100 Ohm differential interfaces. This provides versatility of antenna circuit integration to transceiver chain components on the same board.

The probes utilize several PCB layers coupled through probe via (218) (“thick probes”) and there is a through hole (211) inside the aperture cutout for increasing antenna bandwidth. According to an aspect of the invention, another possibility of using magnetic interaction for testing is to include additional new circuits in DFT parts for structural tests so that additional possibilities with dynamic magnetic fields are created by induction e.g., intervene in SCAN test. Complex logic has the disadvantage that the scan chains have to be loaded often to reach sufficiently high test coverage (it should be >99% for high quality products). However, most of the circuit area is easy to reach but the chains need to be fully loaded, therefore, additional test options in complex areas have significant impact on test time and test costs.

Although some aspects are described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus. Some or all of the method steps may be executed by (or using) a hardware apparatus, like for example, a microprocessor, a programmable computer or an electronic circuit. In some embodiments, one or more of the most important method steps may be executed by such an apparatus.

Depending on certain implementation requirements, embodiments of the invention can be implemented in hardware or in software. The implementation can be performed using a digital storage medium, for example a floppy disk, a DVD, a Blu-Ray, a CD, a ROM, a PROM, an EPROM, an EEPROM or a FLASH memory, having electronically readable control signals stored thereon, which cooperate (or are capable of cooperating) with a programmable computer system such that the respective method is performed. Therefore, the digital storage medium may be computer readable.

Some embodiments according to the invention include a data carrier having electronically readable control signals, which are capable of cooperating with a programmable computer system, such that one of the methods described herein is performed.

Generally, embodiments of the present invention can be implemented as a computer program product with a program code, the program code being operative for performing one of the methods when the computer program product runs on a computer. The program code may for example be stored on a machine readable carrier.

Other embodiments include the computer program for performing one of the methods described herein, stored on a machine readable carrier.

In other words, an embodiment of the inventive method is, therefore, a computer program having a program code for performing one of the methods described herein, when the computer program runs on a computer.

A further embodiment of the inventive methods is, therefore, a data carrier (or a digital storage medium, or a computer-readable medium) including, recorded thereon, the computer program for performing one of the methods described herein. The data carrier, the digital storage medium or the recorded medium are typically tangible and/or non-transitionary.

A further embodiment of the inventive method is, therefore, a data stream or a sequence of signals representing the computer program for performing one of the methods described herein. The data stream or the sequence of signals may for example be configured to be transferred via a data communication connection, for example via the Internet.

A further embodiment according to the invention includes an apparatus or a system configured to transfer (for example, electronically or optically) a computer program for performing one of the methods described herein to a receiver. The receiver may, for example, be a computer, a mobile device, a memory device or the like. The apparatus or system may, for example, include a file server for transferring the computer program to the receiver.

In some embodiments, a programmable logic device (for example a field programmable gate array) may be used to perform some or all of the functionalities of the methods described herein. In some embodiments, a field programmable gate array may cooperate with a microprocessor in order to perform one of the methods described herein. Generally, the methods are performed by any hardware apparatus.

The apparatus described herein may be implemented using a hardware apparatus, or using a computer, or using a combination of a hardware apparatus and a computer.

The apparatus described herein, or any components of the apparatus described herein, may be implemented at least partially in hardware and/or in software.

The methods described herein may be performed using a hardware apparatus, or using a computer, or using a combination of a hardware apparatus and a computer.

The methods described herein, or any components of the apparatus described herein, may be performed at least partially by hardware and/or by software.

While this invention has been described in terms of several advantageous embodiments, there are alterations, permutations, and equivalents, which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

Embodiments of the present invention are thus described. While the present invention has been described in particular embodiments, it should be appreciated that the present invention should not be construed as limited by such embodiments, but rather construed according to the following claims.

What is claimed is:

1. Antenna device, comprising:
a cavity;
a waveguide backshort; and
a printed circuit board (PCB), wherein the PCB comprises an opening and is operable to accommodate at least two probes on a portion of the PCB disposed orthogonally to each other, wherein the cavity is arranged between the portion of the PCB accommodating the probes and the waveguide backshort, wherein the cavity is configured to form a dual-polarized waveguide between the portion of the PCB accommodating the probes and the waveguide backshort, wherein the opening in the PCB is arranged in a central area around a central axis of the cavity, and wherein further the cavity comprises a depth of a quarter wavelength plus an integer multiple of half the wavelength, within a tolerance of +/− 1/16 of the wavelength.

2. The antenna device according to claim 1, wherein the at least two probes are accommodated on the PCB in an area of the PCB surrounding the cavity located between the PCB and the waveguide backshort.

3. The antenna device according to claim 1, wherein the probes comprise at least one orthogonal pair of probes, and wherein further the probes are operable to excite at least two orthogonal modes of the waveguide.

4. The antenna device according to claim 1, further comprising:
at least two microstrip lines disposed on the PCB in an area of the PCB which does not surround the cavity between the PCB and the waveguide backshort, wherein further the at least two probes are connected to the at least two microstrip lines, and wherein the at least two microstrip lines form respective feeding networks for the at least two probes.

5. The antenna device according to claim 4, further comprising:
at least two differential ports; and
at least two differential line transitions, wherein the respective feeding networks of the at least two probes are coupled to respective differential ports out of the at least two differential ports via respective differential line transitions of the at least two differential line transitions.

6. The antenna device according to claim 4, wherein a first feeding network of the respective feeding networks of the probes has a first orientation, and wherein a second feeding network of the respective feeding networks of the probes has a second orientation orthogonal to the first orientation, and wherein the first and second feeding networks are disposed on different layers of the PCB.

7. The antenna device according to claim 1, wherein four probes are operable to be accommodated by the PCB in an area of the PCB that surrounds the cavity disposed between the PCB and the waveguide backshort, wherein the four probes are disposed on the PCB in two orthogonal pairs, and wherein further the four probes are operable to excite main orthogonal modes, TE₁₀ and TE₀₁, of the waveguide.

8. The antenna device according to claim 7, further comprising:
a first differential port;
a second differential port; and
four microstrip lines, wherein the four microstrip lines are disposed on the PCB in an area of the PCB that does not surround the cavity disposed between the PCB and the waveguide backshort, and wherein the four probes are coupled with respective microstrip lines of the four microstrip lines.

9. The antenna device according to claim 1, further comprising a metal base plate, wherein the PCB is disposed on a surface of the metal base plate, and wherein the cavity passes through the metal base plate.

10. The antenna device according to claim 1, wherein the PCB comprises a multi-layer PCB, wherein the waveguide backshort is implemented using a layer of the PCB, and wherein the multi-layer PCB comprises vias around the cavity.

11. The antenna device according to claim 1, wherein the cavity comprises a width of half a wavelength, and wherein the at least two probes comprise a length that is equal to the depth of the cavity within a tolerance of 1/16 of the wavelength.

12. The antenna device according to claim 1, wherein the at least two probes are operable to pass through multiple layers of the PCB through a probe via.

13. The antenna device according to claim 1, further comprising an upper metal plate, wherein an additional waveguide portion is formed in the upper metal plate, wherein the additional waveguide portion extends the waveguide formed by the cavity.

14. The antenna device according to claim 13, further comprising a metal base plate, wherein the PCB is disposed between the metal base plate and the upper metal plate, and wherein the cavity passes through the metal base plate.

15. The antenna device according to claim 1, further comprising a plurality of external connections, wherein a first external connection of the plurality of external connections is operable to be coupled with one or more of the at least two probes having a first orientation, and wherein a second external connection of the plurality of external connections is operable to be coupled with one or more of the at least two probes having a second orientation.

16. The antenna device according to claim 15, wherein the plurality of external connections comprise blind mating waveguide connections, and wherein the plurality of external connections are aligned towards a main radiation direction.

17. The antenna device according to claim 1, further comprising a radio transparent cover that substantially covers the waveguide, and is operable to push a device under test into a device under test location while allowing for a transit of electromagnetic radiation between the waveguide to the device under test.

18. An automated test equipment (ATE), comprising:
an antenna device comprising:
a cavity;
a waveguide backshort; and
a printed circuit board (PCB), wherein the PCB comprises an opening,
wherein the PCB is operable to accommodate at least two probes on a portion of the PCB orthogonally to each other, wherein the cavity is arranged between the portion of the PCB accommodating the probes and the waveguide backshort, wherein the cavity is configured to form a dual-polarized waveguide between the portion of the PCB accommodating the probes and the waveguide backshort, wherein the opening in the printed circuit board is arranged in a central area around a central axis of the cavity, and wherein further the cavity comprises a depth of a quarter wavelength plus an integer multiple of half the wavelength, within a tolerance of +/− 1/16 of the wavelength; and
measurement instrumentation, wherein the measurement instrumentation is operable to test a device under test using the antenna device.

19. The automated test equipment according to claim 18, further comprising:
a device under test (DUT) socket; and
one or more high frequency connectors arranged proximate to the DUT socket.

20. Automated test equipment according to claim 19, wherein the antenna device further comprises:
one or more external connections; and
a cover, wherein the one or more external connections are operable to couple with the one or more high frequency connectors, and wherein the cover is operable to push the device under test into the device under test socket when the one or more external connections of the antenna device couple with the one or more high frequency connectors.
